(19) United States
(12) Patent Application Publication
(10) Pub. No.: US 2009/0194781 A1
(43) Pub. Date: Aug. 6, 2009

(54) WAVELENGTH CONVERSION MEMBER, LIGHT-EMITTING DEVICE AND PHOSPHOR

(75) Inventor: Masamichi Harada, Kitakatsuragi-gun (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA, Osaka-shi (JP)

(21) Appl. No.: 12/354,068

(22) Filed: Jan. 15, 2009

(30) Foreign Application Priority Data
Jan. 18, 2008 (JP) 2008-009106

(51) Int. Cl. H01L 33/00; C09K 11/70

(52) U.S. Cl. 257/98; 252/301.4 P; 257/E33.055

(57) ABSTRACT

A wavelength conversion member provided with a composite phosphor obtained by coating surfaces of phosphor particles with coating material particles and has an average particle diameter of the coating material of not more than 1/10 of an average particle diameter of the phosphor particles, and a light emitting device using the same. It is possible to control dispersibility of the phosphor particles in the wavelength conversion member, and it is possible to provide a light emitting device free from color variability and having good light emission efficiency by combining the wavelength conversion member with a semiconductor light emitting element.

This nonprovisional application is based on Japanese Patent Application No. 2008-009106 filed on Jan. 18, 2008 with the Japan Patent Office, the entire contents of which are hereby incorporated by reference.

### BACKGROUND OF THE INVENTION

1. Field of the Invention

The present invention relates to a wavelength conversion member, a light emitting device provided with the wavelength conversion member, and a phosphor.

2. Description of the Background Art

Since a light emitting device converting light emitted from a semiconductor light emitting element such as a light emitting diode (LED) by a phosphor is small in size, suppressed in power consumption as compared to an incandescent light bulb, and capable of emit light of a color such as white depending on intended use, it is possible to use the light emitting device for a liquid crystal display, a backlight light source of a mobile phone or personal digital assistant, a display device used for indoor/outdoor advertisement, an indicator of various mobile appliances, an illumination switch, a light source for an OA (office automation) appliance, or the like, and development for achieving high efficiency or high reliability has been conducted.

Development for a light emitting device using a semiconductor light emitting element emitting blue or bluish violet light or an ultraviolet ray and a phosphor in combination has heretofore been conducted, and various phosphors of oxides and sulfides have mainly been used as the phosphor.

However, some phosphors such as a phosphor containing a sulfide raise the risk of hydrolysis due to reaction with moisture in the air. A durable period of the light emitting device is reduced by such deterioration of the phosphor. As a countermeasure, a phosphor having a water-proof coating film on surfaces of oxide- and sulfide-based phosphor particles is disclosed in Japanese Patent Laying-Open No. 2002-223008.

Also, Japanese Patent Laying-Open No. 2002-173675 discloses, as a countermeasure for deterioration by an ultraviolet ray and deterioration by moisture, a coating film formation method including a step of forming a sol by dissolving a ceramic precursor such as metal alkoxide or polysilazane into an organic solvent; a step of forming a coating film of the metal alkoxide or the ceramic precursor on a surface of a phosphor by spraying the sol on a particulate phosphor; and a step of forming a coating layer formed of glass or ceramic on the surface of the phosphor by calcining a coating film within a temperature range of 120° C. to 160° C.

Also, in recent years, examples using an oxynitride or nitride phosphor in place of an oxide- or sulfide-based phosphor are disclosed in Japanese Patent Laying-Open Nos. 2002-363554 and 2003-206481. Many of such phosphors are excited by light having a wavelength of 390 to 420 nm and have excellent characteristics such as being capable emitting light with high efficiency, achieving high stability and water resistance, and being reduced in fluctuation in light emission efficiency due to changes in operating temperature.

In order to further improve heat resistance of the nitride phosphor, Japanese Patent Laying-Open No. 2004-161807 discloses provision of a coating film of a metal nitride-based or metal oxynitride-based material. According to the publication, the phosphor particles are covered with a coating film containing an N element since baking deterioration can easily occur when producing (Srₐ, Ca_{1·a})ₓSi_{y}O_{z}N_{{(2/3)x+(4/3)y·(2/3)z}}: Eu(x=2, y=5). As the coating film containing an N element, a metal nitride-based material containing nitrogen and a metal such as aluminum, silicon, titanium, boron, or zirconium or an organic resin containing an N element such as polyurethane or polyurea is used. It is described that a nitride-based phosphor on which the coating film containing an N element is not formed is sharply reduced in light emission efficiency when heated to 200° C. to 300° C., while the provision of the coating film containing an N element suppresses decomposition of nitrogen of the nitride-based phosphor material by the supply of nitrogen to improve heat resistance.

Also, as one example of forming a coating film on surfaces of phosphor particles in an aim different from that of improving chemical stability and heat resistance of a phosphor, Japanese Patent Laying-Open No. 2006-232949 discloses an example aiming at improving dispersibility in a resin. The method is for coating surfaces of phosphor particles with a metal oxide, wherein a metal composing the metal oxide is used as a central atom, and a treatment solution containing a metal complex ion having fluorine as a ligand and water is brought into contact with the phosphor particles to cause a fluoride ion generated by a reaction between the metal complex ion and water to exert an etching action on surfaces of the phosphor particles, thereby enabling to eliminate a defective part of the surfaces of the phosphor particles as well as to dissociate the phosphor particles formed into an aggregate due to necking. Subsequently, the surfaces of the phosphor particles are coated with the metal oxide generated by a reaction between the metal complex ion and water caused on the surfaces of the phosphor particles. It is described that it is possible to improve dispersibility in a resin as well as to improve fluorescence properties by such a treatment.

As described above, the reason for providing a coating film on phosphor particles has been improvements in chemical stability and heat resistance of the phosphor. Also, a technique for the purpose of improving dispersibility of phosphor particles in a medium such as a resin has recently been disclosed.

It is highly likely that particularly the coating film exerts influences on the dispersibility of the phosphor particles in a sealant such as a resin. For example, secondary aggregation of the phosphor particles can occur in the resin when the phosphor particles are dispersed in the resin, and the secondary aggregation can cause color variability of fluorescence and a reduction in light emission efficiency.

Further, in the case of dispersing two or more types of phosphor particles in a medium such as a resin, the dispersibilities of the phosphor particles with respect to the medium may be different from each other. Particularly, in the case where the average particle diameters of the phosphor particles are largely different from each other, the phosphor particles having the larger particle diameter are sedimented to be the cause of the reduction in light emission efficiency. For example, in the case where green phosphor particles and red phosphor particles are dispersed in a resin and the green phosphor particles are sedimented, green light emitted by the green phosphor is re-absorbed by the red phosphor to reduce light emission efficiency.

### SUMMARY OF THE INVENTION

In view of the above, according to one aspect of the present invention, an object of the present invention is, considering a medium such as a resin covering surfaces of phosphor particles, to provide a wavelength conversion member that is improved in dispersibility of the phosphor particles in the medium.

According to another aspect of the present invention, an object of the present invention is to provide a light emitting device capable of controlling dispersibility of phosphor particles and being free from color variability and achieving good light emission efficiency when combined with a semiconductor light emitting element in the wavelength conversion member.

Also, according to another aspect of the present invention, an object of the present invention is to provide a composite phosphor having good dispersibility.

The present invention relates to a wavelength conversion member including a composite phosphor obtained by coating surfaces of phosphor particles with coating material particles and has an average particle diameter of the coating material particles of not more than 1/10 of an average particle diameter of the phosphor particles.

It is preferable that the wavelength conversion member of the present invention further includes phosphor particles.

It is preferable in the wavelength conversion member of the present invention that the composite phosphor is obtained by coating the surfaces of the phosphor particles with the coating material particles by spray drying.

It is preferable in the wavelength conversion member of the present invention that the phosphor particles are an oxynitride or a nitride.

It is preferable in the wavelength conversion member of the present invention that the oxynitride includes Si, Al, O, N, and at least one kind of lanthanoid-based rare earth element(s) as component element(s).

It is preferable in the wavelength conversion member of the present invention that the oxynitride includes one kind selected from a Ce-activated JEM phosphor, an Eu-activated β sialon phosphor, a Ce-activated α sialon phosphor, and an Eu-activated α sialon phosphor.

It is preferable in the wavelength conversion member of the present invention that the nitride includes Ca, Si, Al, N, and at least one kind of lanthanoid-based rare earth element(s) as component element(s).

It is preferable in the wavelength conversion member of the present invention that the nitride includes Eu-activated CaAlSiN₃.

It is preferable in the wavelength conversion member of the present invention that the coating material particles include a metal oxide.

It is preferable in the wavelength conversion member of the present invention that the coating material particles include one kind selected from magnesium oxide, aluminum oxide, and yttrium oxide.

It is preferable in the wavelength conversion member of the present invention that the coating material particles include silicon dioxide.

It is preferable in the wavelength conversion member of the present invention that the coating material particles include a silicone resin.

In the wavelength conversion member of the present invention, it is preferable that a first phosphor having a fluorescence peak wavelength of not less than 500 nm to less than 600 nm and a second phosphor having a fluorescence peak wavelength of not less than 600 nm to not more than 700 nm are dispersed in the medium, and at least one of the first phosphor and the second phosphor is the composite phosphor, it is more preferable that the second phosphor is the phosphor particles, and it is particularly preferable that the second phosphor is dispersed in a region of a lower layer in a thickness direction in the medium.

In the wavelength conversion member of the present invention, it is preferable that a first phosphor having a fluorescence peak wavelength of not less than 500 nm to less than 600 nm, a second phosphor having a fluorescence peak wavelength of not less than 600 nm to not more than 700 nm, and a third phosphor having a fluorescence peak wavelength of not less than 400 nm to less than 500 mm are dispersed in the medium, and at least one of the first phosphor, the second phosphor, and the third phosphor is the composite phosphor, it is more preferable that the second phosphor is the phosphor particles, and it is particularly preferable that the second phosphor is dispersed in a region of a lower layer in a thickness direction in the medium.

In the wavelength conversion member of the present invention, it is preferable that the first phosphor is dispersed in a region of an intermediate layer; the second phosphor is dispersed in a region of a lower layer; and the third phosphor is dispersed in a region of an upper layer in a thickness direction in the medium.

In the wavelength conversion member of the present invention, it is preferable that the first phosphor is a composite phosphor obtained by coating the phosphor particles with silicon dioxide or silicone resin particles; and the third phosphor is a composite phosphor obtained by coating the phosphor particles with yttrium oxide, aluminum oxide, or magnesium oxide.

In the wavelength conversion member of the present invention, it is preferable that the medium is a silicone resin.

The present invention relates to a light emitting device including the above-described wavelength conversion member and a semiconductor light emitting element.

In the light emitting device of the present invention, it is preferable that the semiconductor light emitting element has an emission peak wavelength of not less than 440 nm to not more than 470 nm.

In the light emitting device of the present invention, it is preferable that the semiconductor light emitting element has an emission peak wavelength of not less than 390 nm to not more than 420 nm.

In the light emitting device of the present invention, it is preferable that the semiconductor light emitting element is a GaN-based semiconductor.

The present invention relates to a composite phosphor obtained by coating surfaces of phosphor particles with coating material particles, wherein the coating material particles have an average particle diameter of not more than 1/10 of an average particle diameter of the phosphor particles.

In the composite phosphor of the present invention, it is preferable that the phosphor particles are an oxynitride or a nitride.

In the composite phosphor of the present invention, it is preferable that the oxynitride includes Si, Al, O, N, and at least one kind of lanthanoid-based rare earth element(s) as component element(s).

In the composite phosphor of the present invention, it is preferable that the oxynitride includes one kind selected from a Ce-activated JEM phosphor, an Eu-activated β sialon phosphor, a Ce-activated α sialon phosphor, and an Eu-activated α sialon phosphor.

In the composite phosphor of the present invention, it is preferable that the nitride includes Ca, Si, Al, N, and at least one kind of lanthanoid-based rare earth element(s) as component element(s).

In the composite phosphor of the present invention, it is preferable that the nitride includes Eu-activated CaAlSiN₃.

In the composite phosphor of the present invention, it is preferable that the coating material particles include a metal oxide.

In the composite phosphor of the present invention, it is preferable that the coating material particles include one kind selected from magnesium oxide, aluminum oxide, and yttrium oxide.

In the composite phosphor of the present invention, it is preferable that the coating material particles include silicon dioxide.

In the composite phosphor of the present invention, it is preferable that the coating material particles include a silicone resin.

The present invention enables to provide a wavelength conversion member in which a phosphor is uniformly dispersed. Also, in the wavelength conversion member of the present invention, it is possible to provide a wavelength conversion member free from color variability. Also, when the wavelength conversion member and a semiconductor light emitting element are used in combination, a light emitting device having good light emission efficiency is provided. Also, it is possible to provide a composite phosphor having good dispersibility.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic sectional view showing a light emitting device provided with a wavelength conversion member according to a first embodiment of the present invention.

FIG. 2 is a schematic sectional view showing a composite phosphor provided in the wavelength conversion member of the present invention.

FIG. 3 is a picture of an SEM image of a composite phosphor provided in the wavelength conversion member of the present invention and obtained by coating phosphor particles made from β sialon with yttrium oxide particles used as coating particles.

FIG. 4 is a schematic sectional view showing a light emitting device provided with a wavelength conversion member according to a second embodiment of the present invention.

FIG. 5 is a schematic sectional view showing a light emitting device provided with a wavelength conversion member according to a third embodiment of the present invention.

FIG. 6 is a schematic sectional view showing a light emitting device provided with a wavelength conversion member according to a fourth embodiment of the present invention.

FIG. 7 is a schematic sectional view showing a light emitting device provided with a wavelength conversion member according to a comparative example.

FIG. 8 is a graph showing a particle size distribution of β sialon green phosphor particles.

FIG. 9 is a graph showing a particle size distribution of a composite phosphor of Example 1 obtained by coating β sialon green phosphor particles with coating material particles made from magnesium oxide.

FIG. 10 is a graph showing an evaluation of dispersibility in Example 3.

### DESCRIPTION OF THE PREFERRED EMBODIMENTS

Hereinafter, in the drawings of this application, identical parts or corresponding parts are denoted by an identical reference numeral. Also, dimensions in the drawings such as length, size, and width are appropriately modified for clarity and simplicity of the drawings and do not represent the actual dimensions.

### First Embodiment

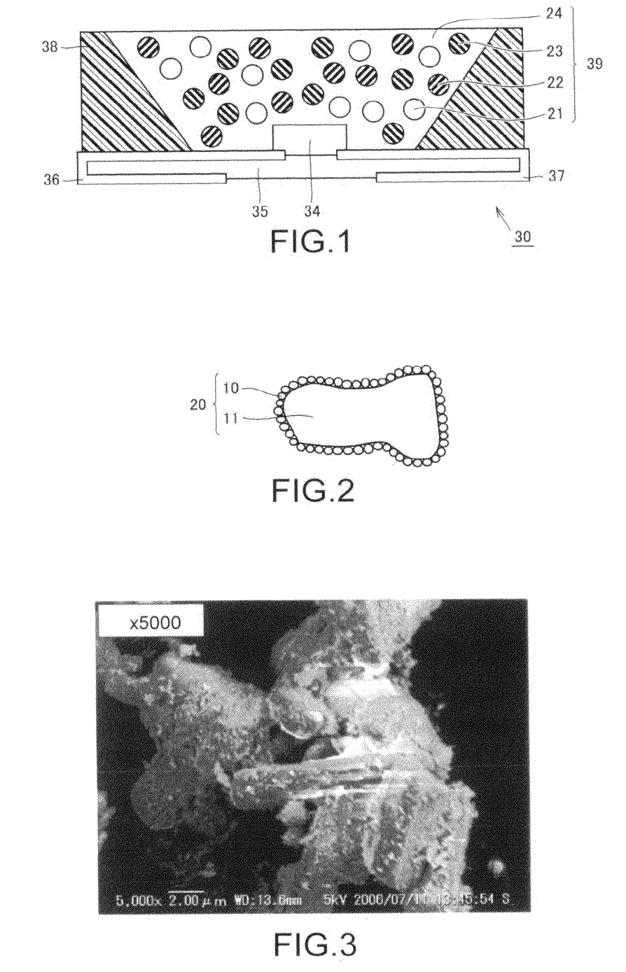

FIG. 1 is a schematic sectional view showing a light emitting device provided with a wavelength conversion member according to a first embodiment of the present invention. FIG. 2 is a schematic sectional view showing a composite phosphor provided in the wavelength conversion member of the present invention. FIG. 3 is a picture of an SEM image of a composite phosphor provided in the wavelength conversion member of the present invention and obtained by coating phosphor particles made from β sialon with yttrium oxide particles used as coating particles.

Hereinafter, description will be given based on FIG. 1, FIG. 2, and FIG. 3. A light emitting device 30 shown in FIG. 1 is provided with a substrate 35, an n-type electrode 36 and a p-type electrode 37 formed on a surface of substrate 35, a semiconductor light emitting element 34 electrically connected to n-type electrode 36 and p-type electrode 37, a resin frame 38 including a mirror on an inclined surface, and a wavelength conversion member 39 for sealing semiconductor light emitting element 34 and converting light emitted from semiconductor light emitting element 34 into fluorescence. Wavelength conversion member 39 is formed of a first phosphor 21, a second phosphor 22, and a third phosphor 23 that are appropriately dispersed in a medium 24. First phosphor 21, second phosphor 22, and third phosphor 23 will be described later in this specification.

Fluorescence is emitted when the phosphors in wavelength conversion member 39 absorb excited light emitted from semiconductor light emitting element 34, and the fluorescence is converted into light of a desired color by wavelength conversion member 39, so that light of the desired color is discharged from light emitting device 30. It is possible to appropriately select the wavelength of semiconductor light emitting element 34 depending on the type of the phosphor to be dispersed in wavelength conversion member 39.

Hereinafter, wavelength conversion member 39 according to this embodiment will be described in detail. Wavelength conversion member 39 is provided with at least one of the first phosphor, the second phosphor, and the third phosphor as a composite phosphor. In this embodiment, it is sufficient that any one of the first phosphor, the second phosphor, and the third phosphor be the composite phosphor.

As shown in FIG. 2, a composite phosphor 20 in this embodiment is phosphor particles 11 to whose surfaces a plurality of coating material particles 10 adhere so that at least a part of phosphor particles 11 is coated with coating material particles 10. In this embodiment, the term “phosphor particles 11” means those not coated with coating material particles 10.

The state of phosphor particles 11 coated with coating material particles 10 as composite phosphor 20 is shown in FIG. 3. Composite phosphor 20 in this embodiment is obtained by coating phosphor particles 11 having poor dispersibility with coating material particles 10. Also, it is unnecessary to coat phosphor particles 11 having good dispersibility with coating material particles 10. The dispersibility in this embodiment is determined by way of compatibility between a material of phosphor particles 11 and a material of medium 24. More specifically, it is possible to conduct the determination based on a sedimentation speed, a sedimentation height, and the like of the phosphor particles.

In this embodiment, an average particle diameter of coating material particles 10 has to be not more than 1/10 of an average particle diameter of phosphor particles 10. The smaller the average particle diameter of coating material particles 10 than the average particle diameter of phosphor particles 11, the more readily attracted coating material particles 10 to phosphor particles 11 by an intermolecular attractive force and an electrostatic attractive force. Therefore, coating material particles 10 easily adhere to the surfaces of phosphor particles 11.

Also, a method of coating phosphor particles 11 with coating material particles 10 is not limited, and it is preferable to obtain composite phosphor 20 by coating the surfaces of phosphor particles 11 with coating material particles 10 by spray drying. Since spray drying is capable of suppressing mechanical damage of composite phosphor 20, a reduction in light emission efficiency of composite phosphor 20 is suppressed.

Phosphor particles 11 may preferably be an oxynitride or a nitride. The oxynitride or nitride phosphor is capable of attaining highly efficient light emission, high stability and water resistance and is suppressed in fluctuation in light emission efficiency otherwise caused by changes in operating temperature. A Ce-activated α sialon phosphor, an Eu-activated β sialon phosphor, a Ce-activated JEM phosphor, or an Eu-activated α sialon phosphor is preferred, and a phosphor containing Si, A, O, N and one or more kinds of lanthanoid-based rare earth element(s) as component element(s) is also preferred. Among nitrides, those containing Ca, Si, Al, N and one or more kinds of lanthanoid-based rare earth element(s) as component element(s) are preferred, and CaAlSiN₃ is particularly preferred since the nitride is excellent in environment resistance and capable of emitting light at high efficiency by activating the center of light emission of rare earths and the like. The average particle diameter of phosphor particles 11 may preferably be 5 to 30 μm without particular limitation thereto.

Phosphor particles 11 is not particularly limited in shape and may be spherical, rectangular parallelepiped, or polygonal or may have holes or projections, but phosphor particles 11 may preferably be spherical.

Coating material particles 10 may be formed of a single material or may be a mixture formed of a plurality of materials, but coating material particles 10 may preferably contain a metal oxide since metal oxides are generally transparent and stable. Among metal oxides, in view of light extraction efficiency of the phosphor, it is particularly preferable to include one selected from magnesium oxide, aluminum oxide, and yttrium oxide by reason of a refractive index thereof that is between a refractive index of the phosphor and a refractive index of a silicone resin serving as the medium. Also, coating material particles 10 may contain silicon dioxide or a silicone resin.

Even when phosphor particles 11 are inferior in dispersibility, it is possible to prevent aggregation and sedimentation in medium 24 by coating phosphor particles 11 with coating material particles 10. In wavelength conversion member 39 of this embodiment, a dispersion state of the first phosphor, the second phosphor, and the third phosphor becomes uniform in medium 24, thereby making it possible to obtain light emitting device 30 free from color variability and having good light emission efficiency when wavelength conversion member 39 is combined with semiconductor light emitting element 34.

In the case where a metal oxide having a specific dielectric constant that is higher than that of the phosphor itself is used as coating material particles 10, a zeta potential of composite phosphor 20 when dispersed in medium 24 is increased, thereby improving dispersibility. Also, when coating material particles 10 adhere and coat phosphor particles 11, electrons in an excited state on the surfaces of phosphor particles 11 are not brought into a non-excited state due to transition involving light emission, thereby making it possible to lower a surface level that is the cause of a process of causing the non-excited state due to non-radiative transition via the surface level, i.e. of a non-radiative process. Also, since coating material particles 10 act as protection films of phosphor particles 11, composite phosphor 20 is excellent in light emission efficiency and long-term chromaticity stability.

The coating material particles 10 may preferably be a compound that has low absorbance and stable since composite phosphor 20 obtained by coating with such coating material particles 10 has good dispersibility when mixed with medium 24.

In this embodiment, first phosphor 21 means a phosphor having a fluorescence peak wavelength of from not less than 500 nm to less than 600 nm. Second phosphor 22 means a phosphor having a fluorescence peak wavelength of not less than 600 nm to not more than 700 nm. Third phosphor 23 means a phosphor having a fluorescence peak wavelength of from not less than 400 nm to less than 500 nm.

Wavelength conversion member 39 is formed by dispersing a plurality of phosphors that are obtained by coating the phosphor particles with the coating material particles in medium 24 made from a transparent resin such as a silicon resin. The phosphors are appropriately selected from the first phosphor, the second phosphor, and the third phosphor, and the selected phosphors are mixed to be dispersed in medium 24. A material for medium 24 is not particularly limited, and a transparent resin such as a silicone resin, an epoxy resin, or a urethane resin may be used, among which the silicone resin is particularly preferred.

It is possible to produce wavelength conversion member 39 by: adding, to a silicone resin material that is in the form of a liquid and used as a material for the medium 24, a phosphor containing Eu-activated β sialon and serving as first phosphor 21, a phosphor containing Eu-activated CaAlSiN₃ and serving as second phosphor 22, and a phosphor containing Ce-activated α sialon and serving as third phosphor 23, followed by uniform mixing; injecting the mixture onto substrate 35; and curing by appropriate heating. It is possible to uniformly disperse the phosphor in medium 24 since the phosphor is phosphor particles coated with the coating material particles. Note that, in the case of using a phosphor having good dispersibility, it is not always necessary to coat such phosphor with the coating material particles.

In the case where light emitting device 30 emits white light, an emission peak wavelength of semiconductor light emitting element 34 may preferably be not less than 390 nm to not more than 420 nm. By the combination of semiconductor light emitting element 34, first phosphor 21, second phosphor 22, and third phosphor 23, a red reproduction region of light emitting device 30 emitting white light is widened to improve a color rendering property as the white light. In this case, the emission peak wavelength of semiconductor light emitting element 34 may preferably be within a range of not less than 400 nm to not more than 410 nm.

In another mode of this embodiment, light emitting device 30 emitting white light may be provided with wavelength conversion member 39 containing first phosphor 21 and second phosphor 22. In light emitting device 30, semiconductor light emitting element 34 preferably has an emission peak wavelength of not less than 440 nm to not more than 470 nm. By the combination of semiconductor light emitting element 34, first phosphor 21 and second phosphor 22, a red reproduction region of light emitting device 30 emitting white light is widened to improve a color rendering property as the white light without containing third phosphor 23. In this case, the emission peak wavelength of semiconductor light emitting element 34 may preferably be within a range of not less than 445 nm to not more than 460 nm.

As the semiconductor light emitting element, a light emitting diode (LED) formed of a GaN-based semiconductor may preferably be used since such a light emitting diode enables to obtain high emission intensity. In the present invention, the GaN-based semiconductor means a semiconductor containing at least Ga and N and obtained by using Al, In, an n-type dopant, a p-type dopant, and the like when so required. As the semiconductor light emitting element, an LED formed of an organic semiconductor or a zinc oxide semiconductor other than the GaN-based semiconductor may also be used, or a semiconductor laser may be used in place of the GaN-based semiconductor.

In the present invention, it is possible to perform measurements of an emission peak wavelength of the semiconductor light emitting element and an emission spectrum of the phosphor by using a phosphor spectrum measurement device MCPD-7000 (manufactured by Otsuka Electronics Co., Ltd.).

The light emitting device obtained by combining the wavelength conversion member produced by dispersing the phosphor obtained by coating the phosphor particles with the coating partials and the semiconductor light emitting element is excellent in light emission efficiency and long-term chromaticity stability due to the improvement in dispersibility of the phosphor in the wavelength conversion member.

As described above, it is possible to obtain the light emission device that is small in size, capable of achieving substantially white light, and highly efficient by using the wavelength conversion member of the present invention obtained by dispersing the phosphor and the semiconductor light emitting element.

In this embodiment, in the case of dispersing two types or more of phosphor particles or the composite phosphors into the medium of a resin or the like, it is also intended to prevent re-absorption of fluorescence that is emitted by the phosphor having a shorter emission wavelength by sedimenting the phosphor having a longer emission wavelength. By suppressing the dispersibility of the phosphor particles as described above, it is possible to provide a light emission device free from color variability and having good light emission efficiency.

It is possible to further improve the color rendering property of the light emission device described in the foregoing by keeping a half bandwidth of the emission spectrum of each of the first, second, and third phosphors to 50 nm or more.

In the following embodiments, it is possible to use similar phosphors in appropriate combination as the composite phosphor.

### Second Embodiment

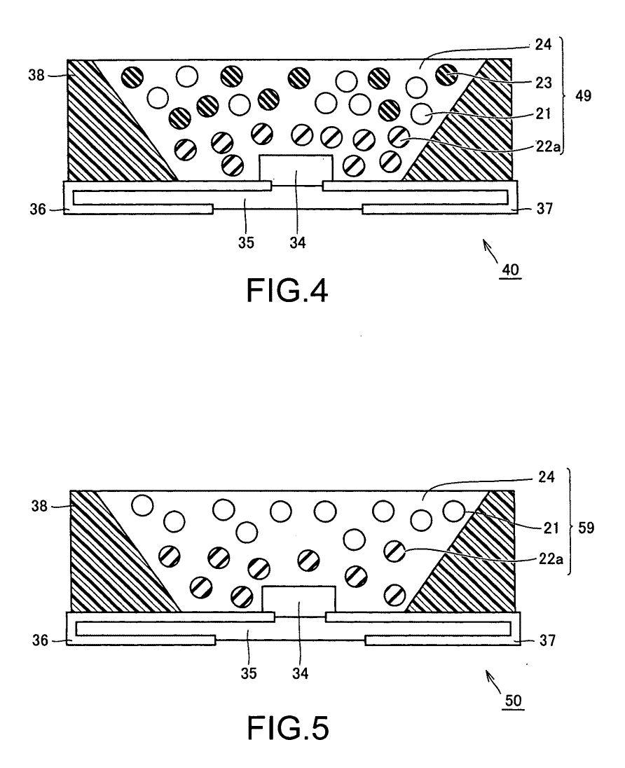

FIG. 4 is a schematic sectional view showing a light emitting device provided with a wavelength conversion member according to a second embodiment of the present invention.

Hereinafter, description will be given based on FIG. 4. In FIG. 4, since a part that is identical or corresponding to that of FIG. 1 is denoted by a reference numeral identical with that of FIG. 1, repetitive description for such a part will not be repeated. A light emitting device 40 in this embodiment is provided with first phosphor 21, a second phosphor 22a formed of phosphor particles, and third phosphor 23 in a wavelength conversion member 49. As described in the foregoing, the second phosphor has a fluorescence peak wavelength of not less than 600 nm to not more than 700 nm and emits red light. In this embodiment, second phosphor 22a is dispersed in a region of a lower layer in a thickness direction of medium 24.

The wording “dispersed in a region of a lower layer” means a state in which 40% to 100% of second phosphor 22a in wavelength conversion member 49 exists in a part which is ⅓ of medium 24 in the thickness direction.

Wavelength conversion member 49 is produced by: adding, to a liquid silicone resin material serving as a material for medium 24, a composite phosphor containing Eu-activated β sialon and serving as first phosphor 21, phosphor particles not coated with coating material particles, containing Eu-activated CaAlSiN₃, and serving as second phosphor 22a, and a composite phosphor containing Ce-activated α sialon and serving as third phosphor 23, followed by uniform mixing; injecting the mixture onto substrate 35; and curing by appropriate heating.

During the silicone resin material is cured by heating, a layer of second phosphor 22a is formed in the region of the lower layer of medium 24 in wavelength conversion member 49. A layer in which first phosphor 21 and second phosphor 22a are mixed is formed on the region of the lower layer. With the above structure, it is possible to suppress re-absorption of blue light emitted by the α sialon blue phosphor particles and green light emitted by the β sialon green phosphor particles by a CaAlSiN₃ red phosphor, thereby making it possible to improve overall light emission efficiency.

In the case where light emitting device 40 emits white light, an emission peak wavelength of semiconductor light emitting element 34 may preferably be not less than 390 nm to not more than 420 nm. By the combination of semiconductor light emitting element 34, first phosphor 21, second phosphor 22a, and third phosphor 23, a red reproduction region of light emitting device 40 emitting white light is widened to improve a color rendering property as the white light. In this case, the emission peak wavelength of semiconductor light emitting element 34 may particularly preferably be within a range of not less than 400 nm to not more than 410 nm. Further, since it is possible to suppress re-absorption of fluorescence of first phosphor 21 and third phosphor 23 by second phosphor 22a, it is possible to improve overall light emission efficiency.

### Third Embodiment

FIG. 5 is a schematic sectional view showing a light emitting device provided with a wavelength conversion member according to a third embodiment of the present invention.

Hereinafter, description will be given based on FIG. 5. In FIG. 5, since a part that is identical or corresponding to that of FIG. 1 is denoted by a reference numeral identical with that of FIG. 1, repetitive description for such a part will not be repeated. A light emitting device 50 in this embodiment is provided with first phosphor 21 and second phosphor 22a formed of phosphor particles in a wavelength conversion member 59. As described in the foregoing, the second phosphor has a fluorescence peak wavelength of not less than 600 nm to not more than 700 nm and emits red light. In this embodiment, second phosphor 22a is dispersed in a region of a lower layer in a thickness direction of medium 24.

Semiconductor light emitting element 34 in light emitting device 50 preferably has an emission peak wavelength of not less than 440 nm to not more than 470 nm. By the combination of semiconductor light emitting element 34, first phosphor 21, and second phosphor 22a, a red reproduction region of light emitting device 50 emitting white light is widened to improve a color rendering property as the white light without using third phosphor 23. In this case, the emission peak wavelength of semiconductor light emitting element 34 may particularly preferably be within a range of not less than 445 nm to not more than 460 nm. Further, since it is possible to suppress re-absorption of fluorescence of first phosphor 21 by second phosphor 22a, it is possible to improve overall light emission efficiency.

### Fourth Embodiment

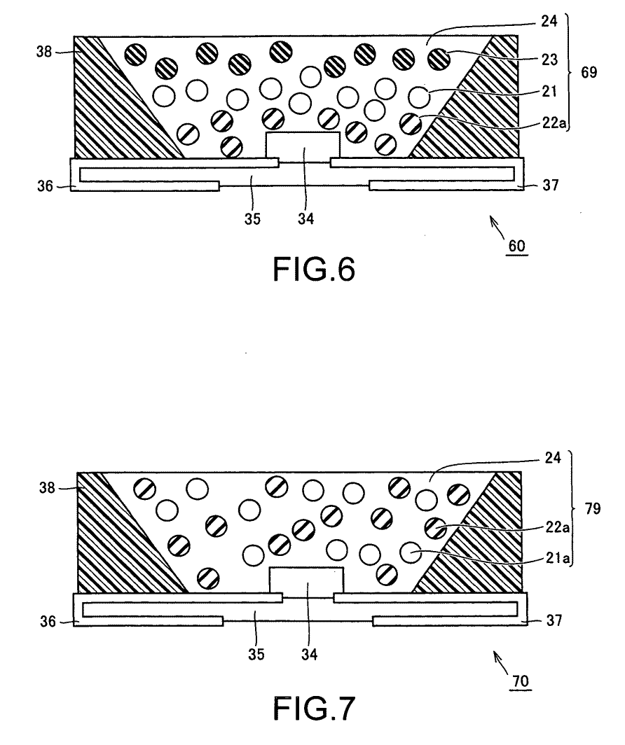

FIG. 6 is a schematic sectional view showing a light emitting device provided with a wavelength conversion member according to a fourth embodiment of the present invention.

Hereinafter, description will be given based on FIG. 6. In FIG. 6, since a part that is identical or corresponding to that of FIG. 1 is denoted by a reference numeral identical with that of FIG. 1, repetitive description for such a part will not be repeated. A light emitting device 60 in this embodiment is provided with first phosphor 21 formed of a composite phosphor, second phosphor 22a formed of phosphor particles, and third phosphor 23 formed of a composite phosphor in a wavelength conversion member 69. As described in the foregoing, the second phosphor has a fluorescence peak wavelength of not less than 600 nm to not more than 700 nm and emits red light. In this embodiment, second phosphor 22a is dispersed in a region of a lower layer in a thickness direction of medium 24.

Also, in this embodiment, first phosphor 21 is dispersed in a region of an intermediate layer; second phosphor 22a is dispersed in the lower layer region; and the phosphor 23 is dispersed in a region of an upper layer in the thickness direction in the medium.

In order to form second phosphor 22a efficiently in the lower layer region, it is preferable to use a metal oxide such as magnesium oxide, aluminum oxide, or yttrium oxide as the coating material particles in third phosphor 23. The case of using the metal oxide as the coating material particles improves the dispersibility as compared to the case of using silicon dioxide or silicon resin particles as the coating material particles. As the coating material particles in first phosphor 21 in this embodiment, it is possible to select silicon dioxide or silicon resin particles.

Since there is the difference in improvement in dispersibility depending on the type of coating material particles, it is possible to adjust the dispersibility of each of the phosphors in medium 24 by appropriately selecting the type of coating material particles in this embodiment.

### Fifth Embodiment

### Composite Phosphor

This embodiment will be described based on FIG. 2. Composite phosphor 20 according to this embodiment is obtained by coating surfaces of phosphor particles 11 with coating material particles 10, and an average particle diameter of coating material particles 10 is not more than 1/10 of an average particle diameter of phosphor particles 11.

As materials for coating material particles 10 and phosphor particles 11, it is possible to use those described in the foregoing, and repetitive descriptions for such materials will not be repeated.

Also, a production method for composite phosphor 20 is not particularly limited, and it is possible to produce composite phosphor 20 by the following first step and second step.

<<First Step>>

In this step, a mixture containing phosphor particles 11 and coating material particles 10 is mixed with a solvent to form a slurry. It is possible to select a desired one for each of phosphor particles 11 and coating material particles 10 forming the slurry. An order for mixing phosphor particles 11 and coating material particles 10 with the slurry is not particularly limited. It is preferable to perform stirring with a stirrer or dispersion by applying ultrasonic wave in order to form a slurry in which phosphor particles 11 and coating material particles 10 are uniformly dispersed in the solvent.

The solvent used for forming the slurry is not particularly limited, and examples thereof include water, methanol, ethanol, n-propanol, n-hexane, acetone, toluene, and the like. In view of the dispersibility of phosphor particles 11 and coating material particles 10, the solvent may preferably be an alcohol, particularly preferably ethanol, because an alcohol has good wettability with phosphor particles 11 and coating material particles 10 to enable more uniform dispersion.

<<Second Step>>

In this step, the slurry formed in the first step is dried by spray drying. The spray drying is a method of spraying a slurry into particles having the size of 5 to 50 nm, for example, and drying the particles. The spray drying may preferably be performed by using a spray drying device provided with a sprayer and a dryer. Examples of a mode of the sprayer include a spraying type and the like. The spray drying includes a spray dryer method and a vacuum drying method. The spray dryer method is a method of drying particles that have been formed by spraying a slurry in a chamber by a swirling hot air stream.

The vacuum drying method is a method of flash freezing particles that have been formed by spraying a slurry and drying the frozen particles in a vacuum dryer.

The device of the spray dryer method may preferably be used as the spray drying device for the spray drying in the present invention since the device is simple in operation and equipments. As the spray drying device employing the spray dryer method, Mini-spray drier B-290 manufactured by Nihon Buchi K. K. or the like may preferably be used.

A drying temperature when spray drying the slurry by the spray dryer method is not particularly limited but may preferably be 100° C. to 200° C. since it is necessary to sufficiently dry the solvent off the slurry.

It is possible to produce composite phosphor 20 wherein surfaces of phosphor particles 11 are coated with coating material particles 10 by undergoing the first step and the second step described above.

Composite phosphor 20 produced by the production method of the present invention is free from mechanical damage and suppressed in reduction in light emission efficiency. Also, composite phosphor 20 has a uniform particle diameter and is excellent in dispersibility to a resin and the like.

Hereinafter, the present invention will be described in more detail in conjunction with examples, but the present invention is not limited to the examples.

### EXAMPLES

### Example 1

### Production of Phosphor

Hereinafter, description will be given with reference to FIG. 2.

<<First Step>>

Eu-activated β sialon green phosphor particles serving as phosphor particles 11 and having an average particle diameter of 14 μm, magnesium oxide serving as coating material particles 10 and having an average particle diameter of 0.05 μm, and ethanol serving as a solvent were prepared.

3.75 g of magnesium oxide and 87.5 ml of ethanol were poured into a beaker, and magnesium oxide was dispersed in ethanol by applying ultrasonic wave. 25 g of the β sialon green phosphor particles were added to the dispersion, and a slurry was obtained by dispersion by further applying ultrasonic wave.

<<Second Step>>

The thus-obtained slurry was subjected to spray drying by a spray drying method at a spraying temperature of 100° C. to 200° C. and a nitrogen flow rate of 350 L/hour with stirring with a stirrer. In this case, Mini-spray drier B-290 manufactured by Nihon Buchi K. K. was used as a device for the spray drying. Composite phosphor 20 wherein the β sialon green phosphor particles were coated with magnesium oxide was produced.

In the thus-obtained composite phosphor 20, evaluation of dispersibility was conducted as follows. 0.1 g of each of the β sialon green phosphor particles and composite phosphor 20 of this example was dispersed in 10 g of ethanol, and a zeta potential was measured. An absolute value of the zeta potential of the phosphor coated with magnesium oxide was about 60 mV, which was larger than an absolute value of the zeta potential of the β sialon green phosphor particles which was about 25 mV. It is considered that composite phosphor 20 wherein the β sialon green phosphor particles were coated with magnesium oxide was improved in dispersibility since composite phosphor 20 was hardly aggregated due to the increased electrical repulsion.

<<Experiment: Particle Size Distribution Measurement>>

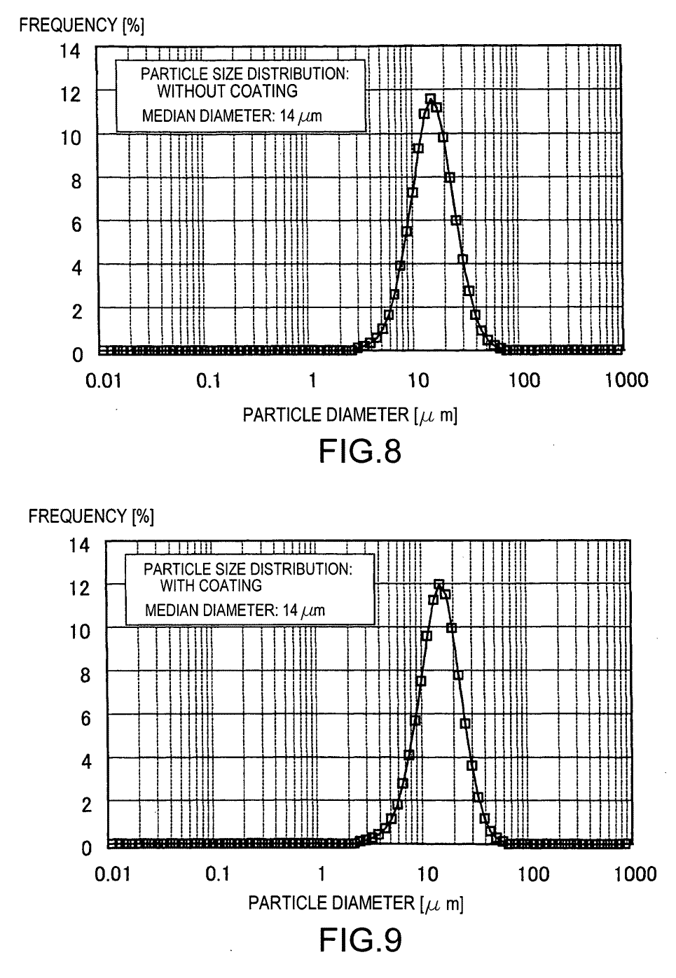

FIG. 8 is a graph indicating a particle size distribution of β sialon green phosphor particles. FIG. 9 is a graph indicating a particle size distribution of a composite phosphor of Example 1 obtained by coating β sialon green phosphor particles with coating material particles made from magnesium oxide.

Hereinafter, description will be given based on FIG. 8 and FIG. 9. A particle size distribution measurement of composite phosphor 20 obtained in Example 1 was performed. For the measurement, a laser diffraction/scattering method particle size distribution measurement device LA-920 manufactured by Horiba was used. As a result, an increase in particle diameter that can easily be caused when using a sol-gel method and resulting from adhesion between phosphor particles did not occur, and it was possible to produce the phosphor having a uniform particle diameter despite the presence of coating material particles.

### Example 2

### Production of Phosphor

Hereinafter, description will be given with reference to FIG. 2.

<<First Step>>

Eu-activated α sialon yellow phosphor particles serving as phosphor particles 11 and having an average particle diameter of 18 μm, yttrium oxide serving as coating material particles 10 and having an average particle diameter of 0.05 μm, and ethanol serving as a solvent were prepared.

3.75 g of yttrium oxide and 87.5 ml of ethanol were poured into a beaker in the same manner as in Example 1, and yttrium oxide was dispersed in ethanol by applying ultrasonic wave. 25 g of the α sialon yellow phosphor particles were added to the dispersion, and a slurry was obtained by dispersion by further applying ultrasonic wave.

<<Second Step>>

The second step was performed in the same manner as in Example 1 to produce composite phosphor 20 wherein the α sialon yellow phosphor particles were coated with yttrium oxide.

<<Experiment: Dispersibility Effect>>

Evaluation of dispersibility of the thus-obtained composite phosphor 20 was performed as follows. 0.5 g of each of the α sialon yellow phosphor particles and composite phosphor 20 of this example was uniformly dispersed in 5 g of a silicone resin and poured into a glass tube to perform a sedimentation test. After leaving the dispersion for 140 hours from the uniform dispersion state, heights of separated supernatants were compared. The height of the transparent supernatant of the α sialon yellow phosphor particles was 1 mm, and the height of the supernatant of the phosphor of this example was almost 0 mm. From these results, it is considered that the dispersibility was improved by coating with yttrium oxide.

### Example 3

### Production of Phosphor

Hereinafter, description will be given with reference to FIG. 2.

<<First Step>>

Eu-activated β sialon green phosphor particles serving as phosphor particles 11 and having an average particle diameter of 14 μm, yttrium oxide having an average particle diameter of 0.05 μm, magnesium oxide, aluminum oxide, silicon dioxide, or silicone resin particles having an average particle diameter of 1 μm and serving as coating material particles 10, and ethanol serving as a solvent were prepared.

3.75 g of each of the coating material particles and 87.5 ml of ethanol were poured into a beaker in the same manner as in Example 1, and the coating material particles were dispersed in ethanol by applying ultrasonic wave. 25 g of the β sialon green phosphor particles were added to the dispersion, and a slurry was obtained by dispersion by further applying ultrasonic wave.

<<Second Step>>

The second step was performed in the same manner as in Example 1 to produce five types of composite phosphors 20, which were obtained by coating the β sialon green phosphor particles with each of five types of coating material particles 10.

<<Experiment: Evaluation of Dispersibility>>

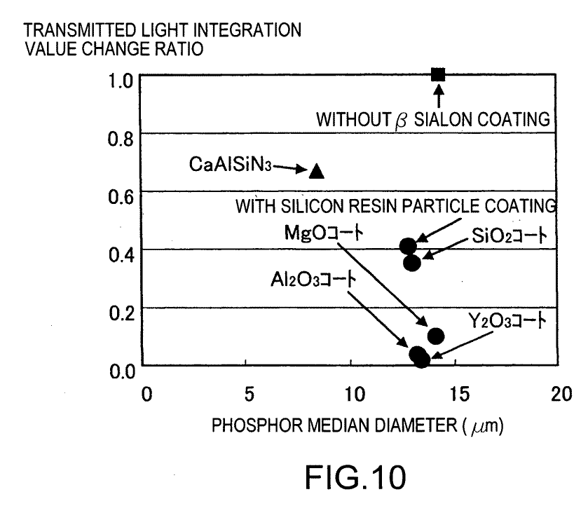

FIG. 10 is a graph showing evaluation of dispersibility. The horizontal axis indicates a median diameter of the composite phosphors or the phosphor particles. The vertical axis indicates a transmitted light integration value change ratio.

Hereinafter, description will be given based on FIG. 10. Evaluation of dispersibility of the five types of composite phosphors 20 obtained as described above was conducted as follows. The dispersibility of a sample prepared by pouring about 1 ml of a silicone resin in which the β sialon phosphor particles coated with the coating material particles was dispersed at a ratio of 10 wt % was evaluated by using a centrifugal sedimentation and light transmissive type dispersion stability analysis device (LUMiSizer 612 manufactured by L.U.M). The dispersibilities were compared by representing a movement of a supernatant in each of the samples by an integration value of a change amount of an amount of light transmitted through the sample per one hour after irradiation of the light.

In FIG. 10, the value in the vertical axis of β sialon phosphor particles whose surfaces were not coated with the coating material particles is regarded as 1. By this experiment, it was revealed that the dispersibility is improved by the coating of the surfaces of the phosphor particles with the coating material particles. The order of excellence of dispersibility of the coating material particles in the composite phosphors was yttrium oxide, aluminum oxide, magnesium oxide, silicon dioxide, and silicone resin particles.

### Example 4

### Production of Light Emitting Device

In the following examples, the following measurement method was employed.

A total light flux emission spectrum measurement and an optical absorption spectrum measurement of the phosphor were conducted (reference literature: Journal of Illuminating Engineering Institute of Japan, Vol. 83, No. 2, 1999, P87-93, Measurement of Quantum Efficiency of NBS Standard Phosphor, written by Kazuaki Okubo, et al.) using an integrating sphere. An emission peak wavelength of the semiconductor light emitting element and an emission spectrum and a fluorescence peak wavelength of the phosphor were measured by using a fluorescence spectrum measurement device “MCPD-7000” (manufactured by Otsuka Electronics Co., Ltd).

Hereinafter, description will be given with reference to FIG. 1.

A light emitting device 30 is provided with a substrate 35, an n-type electrode 36 and a p-type electrode 37 formed on a surface of substrate 35, semiconductor light emitting element 34 electrically connected to n-type electrode 36 and p-type electrode 37, a resin frame 38 including a mirror on an inclined surface, and wavelength conversion member 39 for sealing semiconductor light emitting element 34 and converting light emitted from semiconductor light emitting element 34 into fluorescence. Wavelength conversion member 39 is formed of a silicone resin 24 serving as a medium and first phosphor 21, second phosphor 22, and third phosphor 23 that are dispersed in the resin. First phosphor 21, second phosphor 22, and third phosphor 23 were obtained by performing the coating with magnesium oxide particles in the same manner as described in Example 1 on green phosphor particles made from Eu-activated D sialon, red phosphor particles made from Eu-activated CaAlSiN₃, and blue phosphor particles made from Ce-activated α sialon.

A light emitting diode of a GaN-based semiconductor having an emission peak wavelength of 405 nm was used as semiconductor light emitting element 34.

A fluorescence peak wavelength of first phosphor 21 was 540 nm; a fluorescence peak wavelength of second phosphor 22 was 650 nm; and a fluorescence peak wavelength of third phosphor 23 was 490 nm.

Wavelength conversion member 39 was prepared as described below. First phosphor 21, second phosphor 22, and third phosphor 23 were added to a liquid silicone resin material and uniformly mixed, and the mixture was injected onto substrate 35, followed by heating at 120° C. for 60 minutes for curing. Each of the phosphors was uniformly dispersed in a medium 25. A light emission color of light emitting device 30 of this example in (x, y) values on CIE chromaticity coordinates was almost white with the chromaticity coordinate x of 0.32 and the chromaticity coordinate y of 0.35. Also, the light emitting device was capable of emitting three primary colors and had good color rendering property due to a wide half bandwidth of emission spectrum of each of the phosphors of not less than 50 nm.

### Example 5

### Production of Light Emitting Device

Hereinafter, description will be given with reference to FIG. 5.

Light emitting device 50 is provided with a substrate 35, electrodes 36 and 37 formed on a surface of substrate 35, semiconductor light emitting element 34 electrically connected to electrodes 36 and 37, resin frame 38 including a mirror on an inclined surface, and wavelength conversion member 59 for sealing semiconductor light emitting element 34 and converting light emitted from semiconductor light emitting element 34 into fluorescence. Wavelength conversion member 59 is formed of silicone resin 24 serving as a medium and first phosphor 21 and second phosphor 22a dispersed in the resin. First phosphor 21 was green phosphor particles made from Eu-activated β sialon and obtained by coating with silicon dioxide particles in the same manner as in Example 1. Second phosphor 22a was red phosphor particles made from Eu-activated CaAlSiN₃, and coating was not performed on the phosphor particles. A light emitting diode of a GaN-based semiconductor having an emission peak wavelength of 405 nm was used as semiconductor light emitting element 34.

A fluorescence peak wavelength of first phosphor 21 was 540 nm, and a fluorescence peak of second phosphor 22a was 650 nm.

Wavelength conversion member 59 was prepared as described below. First phosphor 21 and second phosphor 22a were added to a liquid silicone resin material and uniformly mixed, and the mixture was injected onto substrate 35, followed by heating at 120° C. for 60 minutes for curing. No coating was performed on the red phosphor particles made from Eu-activated CaAlSiN₃ serving as a second phosphor and having relatively good dispersibility, and the green phosphor particles made from Eu-activated β sialon serving as a first phosphor and having relatively insufficient dispersibility were improved in dispersibility due to the coating of silicon dioxide as compared to the CaAlSiN₃ red phosphor particles. As a result, in the wavelength conversion member, a layer of the CaAlSiN₃ red phosphor particles was formed at a lower layer side that was close to an LED chip, and a layer in which the β sialon green phosphor particles were dispersed was formed at an upper layer side. A light emission color of light emitting device 50 of this example in (x, y) values on CIE chromaticity coordinates was almost white with the chromaticity coordinate x of 0.30 and the chromaticity coordinate y of 0.30. Also, the light emitting device was capable of emitting three primary colors and had good color rendering property due to a wide half bandwidth of emission spectrum of each of the phosphors of not less than 50 nm. Further, since it was possible to reduce re-adsorption of green light emitted by the β sialon phosphor particles due to the CaAlSiN₃ red phosphor particles in the lower layer, overall light emission efficiency was improved.

### Comparative Example

FIG. 7 is a schematic sectional view showing a light emitting device provided with a wavelength conversion member according to a comparative example.

Hereinafter, description will be given based on FIG. 7. In FIG. 7, since a part that is identical or corresponding to that of FIG. 1 is denoted by a reference numeral identical with that of FIG. 1, repetitive description for such a part will not be repeated. A light emitting device 70 of the comparative example is provided with first phosphor 21a made from Eu-activated β sialon phosphor particles on which no coating was performed and second phosphor 22a made from Eu-activated CaAlSiN₃ phosphor particles on which no coating was performed in a wavelength conversion member 79.

Light emission intensities of the light emitting device of Example 5 and the light emitting device of the comparative example were measured. The light emitting device of Example 5 was improved in light emission intensity by about 5% as compared to the light emitting device of the comparative example. Shown in Table 1 are (x, y) values on CIE chromaticity coordinates and a light emission intensity ratio of light emitting devices of Example 5 and the comparative example.

TABLE 1

| | |
|---|---|
| | Light |
| | Emission |
| Chromaticity | Intensity |

| | X | Y | Ratio |
|---|---|---|---|
| Example 5 | 0.3 | 0.3 | 1.05 |
| Comparative | 0.3 | 0.3 | 1.00 |
| Example | | | |

Although the present invention has been described and illustrated in detail, it is clearly understood that the same is by way of illustration and example only and is not to be taken by way of limitation, the scope of the present invention being interpreted by the terms of the appended claims.

What is claimed is:

1. A wavelength conversion member comprising a composite phosphor obtained by coating surfaces of phosphor particles with coating material particles and has an average particle diameter of said coating material particles of not more than 1/10 of an average particle diameter of said phosphor particles.

2. The wavelength conversion member according to claim 1, further comprising phosphor particles.

3. The wavelength conversion member according to claim 1, wherein said composite phosphor is obtained by coating the surfaces of said phosphor particles with the coating material particles by spray drying.

4. The wavelength conversion member according to claim 1, wherein said phosphor particles are an oxynitride or a nitride.

5. The wavelength conversion member according to claim 4, wherein said oxynitride comprises Si, Al, O, N, and at least one kind of lanthanoid-based rare earth element(s) as component element(s).

6. The wavelength conversion member according to claim 4, wherein said oxynitride comprises one kind selected from a Ce-activated JEM phosphor, an Eu-activated β sialon phosphor, a Ce-activated α sialon phosphor, and an Eu-activated α sialon phosphor.

7. The wavelength conversion member according to claim 4, wherein said nitride comprises Ca, Si, Al, N, and at least one kind of lanthanoid-based rare earth element(s) as component element(s).

8. The wavelength conversion member according to claim 4, wherein said nitride comprises Eu-activated CaAlSiN₃.

9. The wavelength conversion member according to claim 1, wherein said coating material particles comprise a metal oxide.

10. The wavelength conversion member according to claim 1, wherein said coating material particles comprise one kind selected from magnesium oxide, aluminum oxide, and yttrium oxide.

11. The wavelength conversion member according to claim 1, wherein said coating material particles comprise silicon dioxide.

12. The wavelength conversion member according to claim 1, wherein said coating material particles comprise a silicone resin.

13. The wavelength conversion member according to claim 1, wherein
a first phosphor having a fluorescence peak wavelength of not less than 500 nm to less than 600 nm and a second phosphor having a fluorescence peak wavelength of not less than 600 nm to not more than 700 nm are dispersed in a medium; and
at least one of said first phosphor and said second phosphor is said composite phosphor.

14. The wavelength conversion member according to claim 13, wherein said second phosphor is said phosphor particles.

15. The wavelength conversion member according to claim 13, wherein said second phosphor is dispersed in a region of a lower layer in a thickness direction in said medium.

16. The wavelength conversion member according to claim 1, wherein
a first phosphor having a fluorescence peak wavelength of not less than 500 nm to less than 600 nm, a second phosphor having a fluorescence peak wavelength of not less than 600 nm to not more than 700 nm, and a third phosphor having a fluorescence peak wavelength of not less than 400 nm to less than 500 nm are dispersed in a medium; and
at least one of said first phosphor, said second phosphor, and said third phosphor is said composite phosphor.

17. The wavelength conversion member according to claim 16, wherein said second phosphor is said phosphor particles.

18. The wavelength conversion member according to claim 16, wherein said second phosphor is dispersed in a region of a lower layer in a thickness direction in said medium.

19. The wavelength conversion member according to claim 16, wherein
said first phosphor is dispersed in a region of an intermediate layer;
said second phosphor is dispersed in a region of a lower layer; and
said third phosphor is dispersed in a region of an upper layer
in a thickness direction in said medium.

20. The wavelength conversion member according to claim 16, wherein said first phosphor is a composite phosphor obtained by coating said phosphor particles with silicon dioxide or silicone resin particles; and
said third phosphor is a composite phosphor obtained by coating said phosphor particles with yttrium oxide, aluminum oxide, or magnesium oxide.

21. The wavelength conversion member according to claim 1, wherein said medium is a silicone resin.

22. A light emitting device comprising the wavelength conversion member according to claim 1 and a semiconductor light emitting element.

23. The light emitting device according to claim 22, wherein said semiconductor light emitting element has an emission peak wavelength of not less than 440 nm to not more than 470 nm.

24. The light emitting device according to claim 22, wherein said semiconductor light emitting element has an emission peak wavelength of not less than 390 nm to not more than 420 nm.

25. The light emitting device according to claim 22, wherein said semiconductor light emitting element is a GaN-based semiconductor.

26. A composite phosphor obtained by coating surfaces of phosphor particles with coating material particles, wherein said coating material particles have an average particle diameter of not more than 1/10 of an average particle diameter of said phosphor particles.

27. The composite phosphor according to claim 26, wherein said phosphor particles are an oxynitride or a nitride.

28. The composite phosphor according to claim 27, wherein said oxynitride comprises Si, Al, O, N, and at least one kind of lanthanoid-based rare earth element(s) as component element(s).

29. The composite phosphor according to claim 27, wherein said oxynitride comprises one kind selected from a Ce-activated JEM phosphor, an Eu-activated β sialon phosphor, a Ce-activated α sialon phosphor, and an Eu-activated α sialon phosphor.

30. The composite phosphor according to claim 27, wherein said nitride comprises Ca, Si, Al, N, and at least one kind of lanthanoid-based rare earth element(s) as component element(s).

31. The composite phosphor according to claim 27, wherein said nitride comprises Eu-activated CaAlSiN₃.

32. The composite phosphor according to claim 26, wherein said coating material particles comprise a metal oxide.

33. The composite phosphor according to claim 26, wherein said coating material particles comprise one kind selected from magnesium oxide, aluminum oxide, and yttrium oxide.

34. The composite phosphor according to claim 26, wherein said coating material particles comprise silicon dioxide.

35. The composite phosphor according to claim 26, wherein the coating material particles comprise a silicone resin.
